(19) United States
(12) Patent Application Publication
(10) Pub. No.: US 2008/0135868 A1
(43) Pub. Date: Jun. 12, 2008

(54) Nitride Semiconductor Light Emitting Element and Method for Manufacturing the Same

(75) Inventors: Hiroaki Okagawa, Hyogo (JP); Shin Hiraoka, Hyogo (JP)

Correspondence Address: WENDEROTH, LIND & PONACK, L.L.P., 2033 K STREET N. W., SUITE 800, WASHINGTON, DC, 20006-1021, US

(73) Assignee: MITSUBISHI CABLE INDUSTRIES, LTD., CHIYODA-KU, TOKYO (JP)

(21) Appl. No.: 11/664,386

(22) PCT Filed: Sep. 29, 2005
(86) PCT No.: PCT/JP05/18489

§ 371 Date: Apr. 27, 2007

(30) Foreign Application Priority Data
Oct. 1, 2004 (JP) 2004-289466

(51) Int. Cl. H01L 33/00

(52) U.S. Cl. 257/99; 438/39; 257/E33.023; 257/E33.064

(57) ABSTRACT

In an element structure of a nitride semiconductor light emitting element, the laminate including a light emitting part having a laminate structure of a first n-type layer 13, a p-type clad layer 15 and an active layer 14 sandwiched between them, and a second n-type layer 16 present at the outer side of the light emitting part and at the p-type clad layer side. When the laminate is to be grown on a substrate 11, the light emitting part has the p-type clad layer 15 placed on the upper side of the second n-type layer 16 is placed on the further upper side of the light emitting part. The second n-type layer 16 is dry-etched to form an exposed surface. An electrode P12 is formed on the surface exposed by dry etching, whereby the electrode P12 becomes a p-side electrode having a low contact resistance, which is used for injecting a hole in the p-type clad layer 15 of the aforementioned light emitting part, even if the electrode P12 is formed in the n-type layer 16.

### TECHNICAL FIELD

The present invention relates to a nitride semiconductor light emitting element having a p-type nitride semiconductor layer and a p-side electrode, which is an electrode for injecting a hole into the layer, and a production method thereof.

### BACKGROUND ART

In recent years, semiconductor elements using nitride semiconductor as a main part have been strenuously developed. Of such elements, light emitting elements capable of generating a light in the visible (green)—near ultraviolet region, such as light emitting diode (LED), laser diode (LD) and the like, have been put to practical use.

Nitride semiconductors are compound semiconductors represented by the formula AlₐIn_{b}Ga_{1-a-b}N (0≦a≦1, 0≦b≦1, 0≦a+b≦1) and have any composition; for example, binary system GaN, AlN, InN, ternary system AlGaN, InGaN, InAlN, quaternary system AlInGaN and the like. The nitride semiconductors also include one wherein a part of III group element is substituted by B (boron), Tl (thallium) and the like, and one wherein a part of N (nitrogen) is substituted by P (phosphorus), As (arsenic), Sb (antimony), Bi (bismuth) and the like.

Since a nitrogen vacancy contained in nitride semiconductors as a defect is n-type defective and acts as an electron donor, the nitride semiconductors become n-type semiconductors even when undoped. When they are doped with elements such as Si (silicon), Ge (germanium), Se (selenium), Te (tellurium), C (carbon) and the like, the n-type conductivity is enhanced. In other words, these elements act as n-type impurities for nitride semiconductors.

In addition, nitride semiconductors can be p-type semiconductors by doping with elements such as Mg (magnesium), Zn (zinc), Be (beryllium), Ca (calcium), Sr (strontium), Ba (barium) and the like. In other words, these elements act as p-type impurities for nitride semiconductors.

FIG. 9 is a schematic view of a conventional nitride LED. The LED in this Figure has a double hetero pn junction type LED structure, which is a typical structure of LEDs using a nitride semiconductor (hereinafter to be referred to as “nitride LED”). The nitride LED is produced by sequentially growing, on a substrate 1 for crystal growth, an n-type contact layer 2, an n-type clad layer 3, an active layer 4, a p-type clad layer 5 and a p-type contact layer 6, which are made of a nitride semiconductor by the metal organic vapor phase growth (MOVPE) method, forming an n-side electrode P1 on the surface of the n-type contact layer 2 exposed by dry etching, and forming a p-side electrode P2 on the surface of the p-type contact layer 6.

The “n-type” shows a layer made of an n-type conductive nitride semiconductor, and the “p-type” shows a layer made of a p-type conductive nitride semiconductor. As used herein, the p-side electrode P2 injects a hole into the p-type contact layer 6 and p-type clad layer 5, which are p-type nitride semiconductor layers.

In conventional nitride LEDs, the p-side electrode P2 is formed from Ni (nickel), Pt (platinum), Pd (palladium), Rh (rhodium) etc., which are metals capable of forming a good ohmic contact with a p-type nitride semiconductor.

To lower the contact resistance of the p-side electrode P2, it is necessary to form the p-side electrode P2 using these metals, and set a high hole concentration of the p-type contact layer 6. Therefore, the p-type contact layer 6 is doped with a large amount of a p-type impurity.

When Mg is used as a p-type impurity, the p-type contact layer 6 is preferably doped with Mg at a high concentration of not less than 1×10²⁰ cm⁻³.

For production of the nitride LED shown in FIG. 9, the p-type clad layer 5 and the p-type contact layer 6 are grown while being doped with a p-type impurity. After growth of a p-type clad layer 5 and a p-type contact layer 6 by the MOVPE method at a growth temperature of about 900° C.-1200° C., when the substrate is cooled to room temperature while flowing ammonia in a growth furnace, the p-type clad layer 5 and the p-type contact layer 6 do not show p-type conductivity but become insulator (i-type). This phenomenon is called hydrogen passivation, and considered to be caused by inactivation of p-type impurity due to a bond formed with hydrogen atom. The hydrogen atom is said to derive from a hydrogen gas supplied as a carrier gas during crystal growth, ammonia supplied as a V-group source gas, or ammonia supplied during cooling.

In this case, the reason for cooling while flowing ammonia in the growth furnace is that nitride semiconductors have comparatively high equilibrium vapor pressure, for example, in the case of GaN, the crystal is decomposed at not less than 600° C. at normal pressure, and the surface is degraded. However, by cooling while flowing ammonia in the growth furnace, the degradation is suppressed.

Thus, when a p-type nitride semiconductor is formed by the MOVPE method, problems occur in that an ammonia flow during cooling after completion of vapor phase growth causes hydrogen passivation, and the absence of an ammonia flow causes degradation of the surface. Therefore, application of the single-step formation method (i.e., method for forming p-type nitride semiconductor by cooling alone without other post-treatment steps such as electron beam irradiation and annealing after growth by the MOVPE method) is considered to be difficult.

Since the single-step formation method is still a preferable method in view of the production efficiency, the study of the method is ongoing and, for example, a method comprising a cooling atmosphere containing 0.1-30 vol % of ammonia after growth, which aims at suppression of hydrogen passivation and simultaneous suppression of n-type defect (nitrogen vacancy) caused by the degradation of the surface (JP-A-2004-103930) and the like have been proposed.

One of the single-step formation methods is a method comprising balancing, in a cooling process after growth of a nitride semiconductor doped with a p-type impurity by the MOVPE method, hydrogen passivation and surface degradation by controlling a method of ammonia supply to the substrate and ammonia concentration in the atmosphere, thereby allowing appearance of the p-type conductivity of the nitride semiconductor. It has been clarified, however, that once the method is applied to the production of a nitride LED having a conventional structure, the contact resistance of p-side electrode P2 does not fall sufficiently even when the ammonia concentration in the cooling atmosphere is decreased to a considerably low level.

### DISCLOSURE OF THE INVENTION

An object of the present invention is to provide a nitride semiconductor light emitting element having a new p-side electrode structure, and a production method thereof.

The present inventors have found that, when an n-type layer grown adjacent to a p-type layer constituting a light emitting part is etched, and an electrode is formed on the etched surface, a hole can be preferably injected from the electrode to a p-type layer, which resulted in the completion of the present invention.

The present invention is characterized by the following.

### (1) A nitride semiconductor light emitting element comprising a laminate made of nitride semiconductor layers, the laminate including;

a light emitting part having a laminate structure of a first n-type layer, a p-type layer and an active layer sandwiched between them, and

a second n-type layer present at the outer side of the light emitting part and at the p-type layer side, wherein

the second n-type layer has a surface exposed by dry etching, and a p-side electrode for injecting a hole into the p-type layer of said light emitting part is formed on the exposed surface.

### (2) The nitride semiconductor light emitting element of (1), wherein the laminate is formed by sequentially growing nitride semiconductor layers on the substrate,

when the substrate is on the lower side, the light emitting part is included in the laminate in such a manner that the first n-type layer is on the lower side and the p-type layer is on the upper side, and

the second n-type layer is located at the upper side of the light emitting part.

### (3) The nitride semiconductor light emitting element of (2), wherein the first n-type layer of the light emitting part simultaneously acts as the n-type contact layer.

(4) The nitride semiconductor light emitting element of the (2), wherein the laminate comprises an exclusive n-type contact layer on the lower side of the n-type layer of the light emitting part, or the substrate is made of an n-type nitride semiconductor and simultaneously acts as the n-type contact layer.

### (5) The nitride semiconductor light emitting element of (3) or (4), wherein the n-type contact layer has a surface exposed by dry etching and an n-side electrode is formed on the surface.

### (6) The nitride semiconductor light emitting element of (1), wherein the entire upper surface of the second n-type layer is dry etched, and the p-side electrode is formed on the dry etched surface.

### (7) The nitride semiconductor light emitting element of (6), wherein the p-side electrode is formed on approximately the entire surface of the dry etched surface.

### (8) The nitride semiconductor light emitting element of (7), wherein the p-side electrode is a transparent electrode, an electrode with an opening or a reflective electrode made of Al or Al alloy.

### (9) The nitride semiconductor light emitting element of (1), wherein the dry etched side of the surface of the above-mentioned second n-type layer is a concavo-convex surface formed by the dry etching.

(10) The nitride semiconductor light emitting element of (9), wherein the surface of the dry etched side of the second n-type layer has a nitride semiconductor layer layered on said surface prior to the dry etching, the dry etching is applied to the second n-type layer from the surface of the layered nitride semiconductor layer to reach the second n-type layer.

### (11) The nitride semiconductor light emitting element of the (9) or (10), wherein the p-side electrode is formed on approximately the entire surface of the concavo-convex surface.

### (12) The nitride semiconductor light emitting element of the (11), wherein the p-side electrode is a transparent electrode or a reflective electrode made of Al or Al alloy.

### (13) The nitride semiconductor light emitting element of (9) or (10), wherein the p-side electrode is formed only in the concave part of the concavo-convex surface, and the p-side electrode is absent in the upper part of the convex part.

### (14) A method for producing a nitride semiconductor light emitting element comprising an element structure wherein a laminate having nitride semiconductor layers is grown on a substrate, which comprises at least

a step of growing a first n-type layer, an active layer, a p-type layer and a second n-type layer in this order on the substrate,

a step of applying dry etching to the upper surface of said second n-type layer, and

a step of forming a p-side electrode on the surface of the second n-type layer which has been exposed by dry etching in said step, the electrode being used for injecting a hole into the p-type layer of the light emitting part.

### BRIEF DESCRIPTION OF THE DRAWINGS

FIG. 1 is an illustrative drawing of one embodiment of the nitride LED structure according to the present invention, wherein hatching is appropriately applied to distinguish the regions (same for other Figures).

FIG. 2 includes illustrative drawings of an embodiment wherein a p-side electrode is formed on the surface of the n-type nitride semiconductor, which surface has been exposed by dry etching in the present invention.

FIG. 3 includes illustrative drawings of an embodiment wherein a p-side electrode is formed on the surface of the n-type nitride semiconductor, which surface has been exposed by dry etching in the present invention.

FIG. 4 includes illustrative drawings of an embodiment wherein a p-side electrode is formed on the surface of the n-type nitride semiconductor, which surface has been exposed by partial dry etching in the present invention.

FIG. 5 includes illustrative drawings of patterns of the concave part formed by dry etching in an embodiment wherein a p-side electrode is formed on the surface of the n-type nitride semiconductor, which surface has been exposed by partial dry etching in the present invention.

FIG. 6 is an illustrative drawing showing one embodiment of the nitride LED structure according to the present invention.

FIG. 7 explains a production step of a nitride LED having the structure shown in FIG. 6. In FIG. 7(b)-(d), reference symbols are provided only to the newly added layers and duplicate provision of the same reference symbols to the same layers has been omitted. In FIGS. 7(a) and (e), reference symbols are provided to all layers for easy understanding.

FIG. 8 is an illustrative drawing showing one embodiment of the nitride LED structure according to the present invention.

FIG. 9 shows a conventional nitride LED structure.

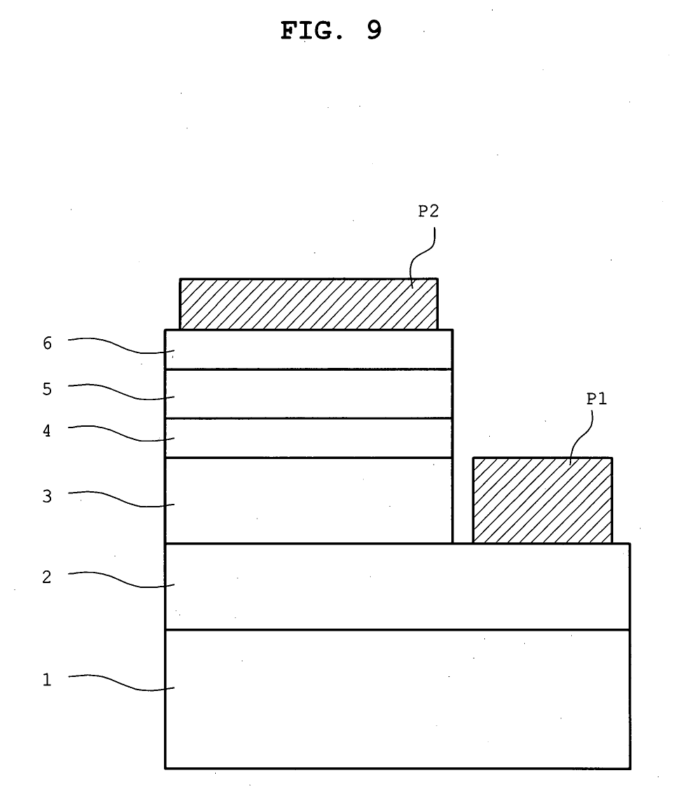

In the Figures, each reference symbol shows the following. 11; sapphire substrate, 12; n-type contact layer, 13; n-type clad layer, 14; active layer, 15; p-type clad layer, 16; p-side contact layer, P11; n-side electrode, P12; p-side electrode.

### BEST MODE FOR EMBODYING THE INVENTION

The embodiments of the invention are explained in the following by referring to the Figures.

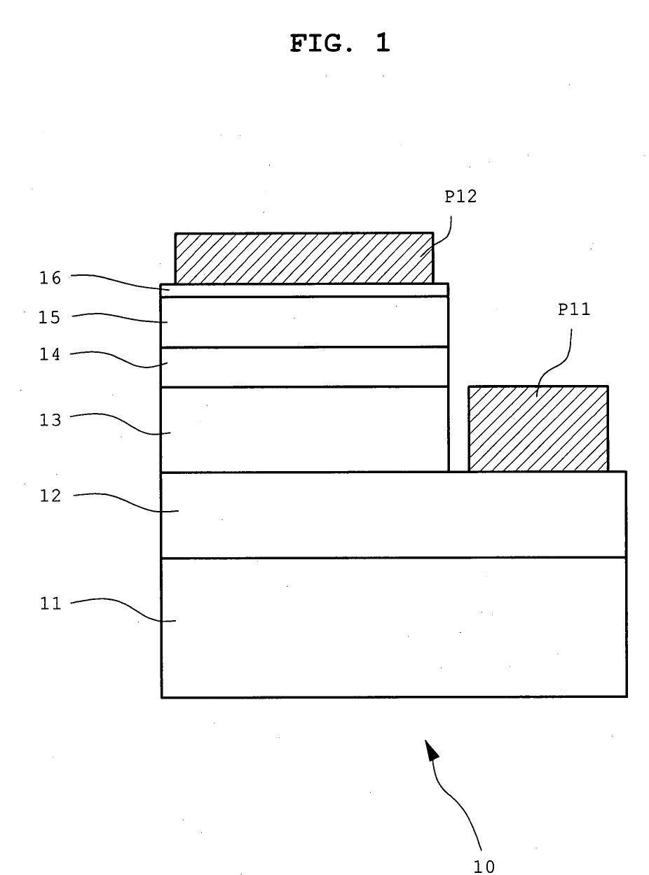

FIG. 1 is a schematic sectional view of one embodiment of the nitride LED structure according to the present invention. The LED 10 has a sapphire substrate 11, and a laminate wherein a GaN buffer layer (not shown), an about 2 μm-thick n-type contact layer 12 made of Si-doped GaN, an about 2 μm-thick n-type clad layer (=the first n-type layer) 13 made of Si-doped AlGaN, an active layer 14 having a multiple quantum well structure wherein a 6 nm-thick GaN barrier layer and a 2 nm-thick InGaN well layer are alternately laminated by 10 layers, a 100 nm thick p-type clad layer 15 made of Mg-doped AlGaN, and a 10 nm thick p-side contact layer (=second n-type layer) 16 made of Si-doped GaN are sequentially grown on the sapphire substrate 11.

The laminate is partly removed by dry etching from the surface of the p-side contact layer 16, which is a second n-type layer, to reach the n-type contact layer 12. Then, an Al/Ti laminate electrode is formed as an n-side electrode P11 on the surface of the exposed n-type contact layer 12. In addition, an Al/Pd/Au laminate electrode, wherein a 50 nm thick Pd layer and a 100 nm thick Au layer are sequentially laminated on a 50 nm thick Al layer, is formed as a p-side electrode P12 on the surface of the remaining p-side contact layer 16 in such a manner that it approximately entirely covers the surface of the p-side contact layer 16. The p-side electrode P12 is an opening electrode which, when seen from the upper surface, is formed in a pattern having an opening exposing the p-side contact layer 16. A pad electrode for wire-bonding has been omitted.

By explaining the semiconductor growing step, substrate cooling step and electrode formation step in detail in the following, the production method of the present invention and the element structure of the present invention are simultaneously explained.

### [Semiconductor Growing Step]

In the semiconductor growing step, nitride semiconductor layers including a buffer layer (not shown), an n-type contact layer 12, a light emitting part (the first n-type layer 13, active layer 14, p-type clad layer 15), and a second n-type layer (p-side contact layer) 16 are grown on a sapphire substrate 11 by the MOVPE method.

As the substrate, conventionally-known substrates usable for epitaxial growth of nitride semiconductor crystals, such as SiC substrate, GaN substrate, AlN substrate, Si substrate, spinel substrate, ZnO substrate, GaAs substrate, NGO substrate and the like can be appropriately used besides the sapphire substrate.

While a laminate formed on a substrate is made from a nitride semiconductor crystal layers, it may, depending on the object, contain a structure made from a material other than nitride semiconductors.

The light emitting part only needs to have a laminate structure wherein an active layer is sandwiched between the first n-type layer and the p-type clad layer, so that a light emitting diode structure that generates light by carrier injection can be constituted. Preferably, a double hetero structure wherein an active layer is sandwiched between the first n-type layer and the p-type clad layer, both having a greater band gap than that of the active layer, is employed. The active layer preferably has a single quantum well (SQW) structure or a multiple quantum well (MQW) structure.

As shown in FIG. 1, when the first n-type layer of the light emitting part is placed on the substrate side, the first n-type layer may be an exclusive n-type clad layer (where an exclusive n-type contact layer is separately formed), or may also function as an n-type contact layer and an n-type clad layer. In the former case, when a substrate made from an n-type nitride semiconductor such as n-type GaN substrate and the like is used as the substrate, the substrate may also be used as an exclusive n-type contact layer. The constitution of these laminate layers may be that of a known nitride semiconductor light emitting element.

A method of growing each nitride semiconductor layer by the MOVPE method is known, with no limitation on the MOVPE apparatus, and the source material, growth conditions and the like of the nitride semiconductor. Thus, conventionally known methods can be appropriately employed for the control system, piping system, growth furnace, metal organic source, gas source, carrier gas, subflow gas, substrate heating method, supply conditions of source material and gas, growth temperature conditions, and others.

The design can also follow known techniques, such as crystal composition, dopant and its concentration, thickness and the like of the nitride semiconductor layer except a p-side contact layer 16 which is a second n-type layer. They are not limited to the constitution shown in FIG. 1, but can be variously deformed in reference to known techniques. As one example, each layer does not need to have the same semiconductor composition or impurity concentration within the layer. For example, p-type clad layer 15 may contain plural layers having different semiconductor compositions and/or impurity concentrations. In addition, the structure of FIG. 1 may be omitted or an additional structure may be incorporated as long as the mechanism of light emission wherein an electron diffusing in the n-type conductive layer and a hole diffusing in the p-type conductive layer are recombined in the active layer to emit light.

For the growth of a p-type clad layer 15 made of Mg-doped AlGaN, trimethyl gallium (TMG) and trimethylaluminum (TMA) can be used as a III-group source material, ammonia can be used as a V-group source material, and bis(cyclopentadienyl)magnesium (Cp₂Mg) can be used as a p-type impurity source. These source materials are supplied to the growth furnace as hydrogen gas carrier gases. To adjust the gas flow near the substrate, nitrogen gas and the like may be flown as a subflow gas into the growth furnace. The substrate temperature is preferably 900° C.-1200° C.

When the p-type clad layer 15 has grown to a given thickness, supply of TMA and Cp₂Mg is stopped. Instead, silane (SiH₄) is supplied to the growth furnace as an n-type impurity source to grow a p-side contact layer 16 made of Si-doped GaN.

The p-side contact layer 16 may be grown at the same temperature as the growth of the p-type clad layer 15, or may be grown at a different temperature.

It is also possible to set a growth interruption time between the growth of the p-type clad layer 15 and the growth of the p-side contact layer 16. During the interruption time, nitride semiconductor is not grown when the ammonia concentration in the atmosphere of the growth furnace is set lower than that during the growth of the p-type clad layer 15.

In the growth interruption time, the surface of the p-type clad layer 15 has not been covered with the p-side contact layer 16, and the ammonia concentration in the atmosphere is lower than that during the growth of p-type clad 15. Thus, hydrogen taken up into the p-type clad layer 15 during growth of p-type clad layer 15 is effectively expelled to the outside from the surface of the p-type clad layer 15. Thus, the hydrogen passivation can be suppressed and the p-type conductivity of the finally-obtained p-type clad layer 15 is improved.

In the aforementioned growth interruption time, a method of lowering the ammonia concentration in the growth furnace atmosphere than that during the growth of p-type clad 15 is not limited. However, a method of lowering the ratio of ammonia in the gas to be supplied to the growth furnace is most convenient and preferable. The ratio of ammonia here may be zero. In that case, however, the surface of the p-type clad layer 15 may be degraded or become rough. Particularly, when the substrate temperature is high, etching occurs to decrease the film thickness of the p-type clad layer 15. Accordingly, it is preferable to not set the ratio of ammonia to zero but supply a gas containing a small amount of ammonia, specifically, a mixed gas of an inactive gas and ammonia is preferably flown. Here, the inactive gas means nitrogen gas, as well as rare gas such as argon, neon, helium and the like.

The flow rate of ammonia in the mixed gas flow to be supplied to the growth furnace during the above-mentioned growth interruption time is preferably less than 2.5%, since, when the flow ratio of ammonia is less than 2.5%, expulsion of hydrogen from the p-type clad layer 15 becomes particularly effective.

The mixed gas here may be a mixture of an inactive gas and ammonia prepared in advance outside the MOVPE apparatus, or an inactive gas and ammonia supplied to the MOVPE apparatus from a separated inactive gas source and an ammonia source, respectively, and mixed in a pipe of the apparatus, in a gas inlet in the upstream of the growth furnace, in a growth furnace and the like. The mixed gas here is not required to be one wherein an inactive gas and ammonia are uniformly mixed at a molecule level.

When a p-side contact layer 16 is growing after the growth interruption time, an ammonia concentration in an atmosphere may be increased again.

By setting the growth temperature T_{CON} of the p-side contact layer 16 to be lower than the growth temperature T_{CL} of a p-type clad 15 and lowering the substrate temperature from T_{CL} to T_{CON} during the above-mentioned growth interruption time, degradation of the exposed surface of the p-type clad layer 15 during the growth interruption time is suppressed.

In this case, T_{CON} which is set lower than T_{CL} is preferably 700° C.-900° C. When T_{CON} is not more than 700° C., crystal quality of the p-side contact layer 16 tends to be degraded, and when it is not less than 900° C., the effect of differing T_{CL} from T_{CON} is reduced.

When a p-side contact layer (second n-type layer) 16 is to be grown to a thickness of 10 nm, it is only necessary to cease supply of the source gas to stop the growth at a thickness of 10 nm. Alternatively, after growth to a thickness of over 10 nm, the supply of the source gas may be stopped and a gas having an etching effect may be supplied to allow etching of the surface to a thickness of 10 nm. As a gas having an etching effect, hydrogen gas can be used.

Although the interface between a p-type clad layer 15 and a p-side contact layer 16 becomes a junction between semiconductors having different conduction types, the contact resistance of a p-side electrode P12 decreases to a practical level. Therefore, tunneling of carrier at the above-mentioned junction is considered to be involved in the injection of hole into the p-type clad layer 15. The tunneling occurs more easily as the electron concentration of the p-side contact layer 16 becomes higher, since it reduces the thickness of barrier.

Accordingly, a preferable electron concentration of the p-side contact layer 16 is not less than 1×10¹⁸ cm⁻³, more preferably not less than 3×10¹⁸ cm⁻³, and still more preferably not less than 5×10¹⁸ cm⁻³. While the electron concentration of the p-side contact layer 16 has no upper limit, when the layer is doped with an impurity at a high electron concentration exceeding 1×10²⁰ cm⁻³, the crystal quality of the nitride semiconductor becomes degraded, rendering control of the conductivity difficult and, when the n-type impurity is Si, the nitride semiconductor tends to grow three-dimensionally and a flat film cannot be grown easily. At an n-type impurity concentration making the electron concentration of not more than 2×10¹⁹ cm⁻³, an n-type nitride semiconductor with good crystallinity can be grown.

Therefore, when the thickness of the p-side contact layer is made more than 10 nm, a high electron concentration layer with a film thickness of not less than 10 nm, which is added with n-type impurity so that the electron concentration will be not less than 2×10¹⁹ cm⁻³, may be grown on a part contacting with the p-type clad layer 15, and after that, a layer having a lower concentration may be grown to flatten the growth surface.

The electron concentration of the p-side contact layer is preferably not less than 1×10¹⁸ cm⁻³, more preferably not less than 3×10¹⁸ cm⁻³, and further preferably not less than 5×10¹⁸ cm⁻³ in view of reducing a contact resistance between a p-side electrode and the p-side contact layer.

The p-side contact layer may have a constitution wherein n-type impurity is added to the parts contacting to the p-type clad layer or the p-side electrode to a higher concentration than other parts.

To reduce the tunneling barrier at the junction of p-type clad layer and p-side contact layer, it is also preferable to increase the p-type carrier concentration of the p-type clad layer near the junction. Therefore, it is preferable to add a p-type impurity such as Mg and the like at a concentration of not less than 1×10¹⁹ cm⁻³, more preferably not less than 1×10²⁰ cm⁻³, to at least the part where the p-type clad layer contacts the p-side contact layer.

In addition to Si-doping of the p-side contact layer 16, it is also preferable to provide a thin Si layer at an interface between the p-type clad layer 15 and the p-side contact layer 16 in view of reducing a contact resistance of a p-side electrode P12.

For this end, supply of the source material is once stopped at the time point when the growth of the p-type clad layer 15 is completed, a silane compound such as tetraethylsilane, disilane, silane and the like is supplied in a gaseous phase to the exposed surface of the p-type clad layer 15 using hydrogen gas as a carrier gas, thus allowing adsorption of Si onto the surface, and the Si-doped p-side contact layer 16 is subsequently grown by the MOVPE method. The thickness of the thus-formed Si layer is estimated to be within the range of not more than a single atom layer-several atom layer.

Such Si layer functions to electrically short-circuit the p-type clad layer 15 and the p-side contact layer 16. While a detailed mechanism is not known, it has an effect to facilitate passage of a carrier through the interface between the p-type clad layer 15 and the p-side contact layer 16.

While the composition of the nitride semiconductor to be used for the p-side contact layer 16 is not limited, it is preferable that the composition have a band gap greater than the energy of the light generated in the active layer 14, so that the light generated in the active layer 14 will not be absorbed by the p-side contact layer 16. When InGaN is used for the active layer 14, a high light-extraction efficiency can be obtained. In this case, using binary GaN crystal as the p-side contact layer 16, good crystallinity can be preferably obtained.

When the composition includes Al, an effect of suppressing surface degradation of the p-side contact layer 16 in the next substrate cooling step can be expected since Al has a stronger binding force to N than Ga and In.

In addition, the p-side contact layer may have a multi-layer structure wherein a nitride semiconductor crystal layer having a different composition is laminated, or a structure wherein the crystal composition is inclined in the thickness direction.

### [Substrate Cooling Step]

In the substrate cooling step, the temperature of the sapphire substrate 11 after completion of the growth of nitride semiconductor layers up to the p-side contact layer 16 is cooled to the room temperature. To prevent the p-type clad layer 15 from becoming insulator (i-type) by hydrogen passivation during the cooling, that is, to allow the p-type clad layer 15 to become p-type conductive at the time point when the cooling is completed, the cooling is performed.

As one embodiment, a method comprising stopping, after completion of the growth of the p-side contact layer 16, supply of TMG, Cp₂Mg as metal organic source, hydrogen gas supplied as a carrier gas and the like, as well as heating of the substrate, and lowering the substrate temperature to room temperature by natural cooling while supplying a small amount of ammonia and an inactive gas into the growth furnace can be mentioned.

As mentioned above, the inactive gas in the context of the present invention means a nitrogen gas and what is called rare gas such as argon, neon, helium and the like. Irrespective of the kind of steps, it is preferable to use an economical nitrogen gas as the inactive gas to be used in the present invention, for reduction of the production cost.

When the growth temperature T_{CON} of the p-side contact layer 16 is higher than 700° C., a method comprising ceasing the heating of the substrate, cooling the substrate until the temperature reaches 700° C. while flowing ammonia into the growth furnace, ceasing the ammonia supply at 700° C., cooling the substrate to 400° C. over not less than 1 min while flowing the inactive gas alone in the growth furnace, and further cooling to room temperature can be mentioned.

It is also possible to stop heating the substrate and ammonia on completion of nitride semiconductor growth, thereby to flow an inactive gas alone into the growth furnace during the cooling step.

In the latter case, since ammonia supply is stopped at a high temperature, the surface degradation of p-side contact layer 16 becomes high. However, since the p-side contact layer 16 is n-type conductive, the influence of the nitrogen vacancy produced by degradation on the electric property is smaller than in the case of a p-type nitride semiconductor.

The method of cooling the substrate and cooling conditions in the substrate cooling step are not limited to the above-mentioned examples.

It is known that a nitride semiconductor crystal grown by the MOVPE method while being added with a p-type impurity becomes a p-type semiconductor when maintained in an atmosphere substantially free of hydrogen causing a hydrogen passivation at a temperature of not less than 400° C. (preferably not less than 700° C.) for about 1 min. Therefore, the cooling method and the cooling conditions for the substrate cooling step of the present invention can be determined to meet such conditions.

Here, the “hydrogen causing a hydrogen passivation” is hydrogen relating to an H—H bond or N—H bond included in hydrogen gas, ammonia, hydrazine and the like. An atmosphere substantially free of such hydrogen refers to an atmosphere that does not contain hydrogen at a concentration causing a hydrogen passivation of a practically problematic level, and does not mean complete absence of hydrogen.

While the gas used as the main component of an atmosphere gas substantially free of “hydrogen causing a hydrogen passivation” is not limited, an inactive gas is preferably used in practice.

When ammonia is flown in the growth furnace in the substrate cooling step, a mixed gas of an inactive gas and ammonia is preferably supplied in the growth furnace to suppress the development of hydrogen passivation as much as possible. The flow ratio of ammonia in the mixed gas is preferably less than 2.5%, more preferably less than 1%, particularly preferably less than 0.5%. When the flow ratio of ammonia is within this range, hydrogen passivation is effectively suppressed and the p-type clad layer 15 easily becomes p-type conductive. Even when the flow ratio of ammonia is about 0.1%, it has an effect of suppressing the surface degradation of the p-side contact layer 16.

The mixed gas here may be a mixed gas prepared in advance by mixing an inactive gas and ammonia outside the MOVPE apparatus, or a mixed gas prepared by mixing, in the piping of the MOVPE apparatus, a gas inlet at the upstream of the growth furnace, in the growth furnace and the like, an inactive gas and ammonia supplied into the MOVPE apparatus from the separate inactive gas source and ammonia source, respectively. The mixed gas is not required to contain an inactive gas and ammonia uniformly mixed at a molecular level.

For suppression of the hydrogen passivation, ammonia to be flown in the growth furnace in the substrate cooling step is preferably stopped before the substrate temperature decreases to 400° C. or below, including the case of using the above-mentioned mixed gas. On the other hand, when T_{CON} is not less than 900° C., ammonia is preferably supplied into the growth furnace at least until the substrate temperature decreases to 900° C., so as to suppress surface degradation of the p-side contact layer 16.

JP-A-2004-103930 and JP-A-2003-297841 may be referred to for a method of cooling in an atmosphere containing ammonia.

By natural cooling where the substrate temperature is allowed to decrease after stopping heating the substrate, the temperature is not artificially controlled. In the present invention, however, the “cooling” operation includes a method of lowering the substrate temperature by natural cooling. Examples of artificial temperature control operation include forcible cooling by a cooling circuit set on a susceptor holding the substrate, alleviation of temperature decrease rate by activating a given susceptor heating means set on the apparatus such as heating with a heater, high frequency heating etc., and the like. In the production method of the present invention, the substrate may be cooled while performing such artificial temperature control operation.

In addition, the temperature profile during cooling may be freely set, where the temperature decrease rate may be changed on the way; or the temperature may not only be monotonously decreased with time but may be maintained at a given level for a certain time, or may be raised for a certain time, though partially.

As a gas capable of suppressing surface degradation of the p-side contact layer 16 by mixing a small amount thereof with an atmosphere gas, compounds that can be a V-group source material in the MOVPE method, such as hydrazine, organic amine and the like, can be mentioned besides ammonia.

Moreover, the substrate cooling step may be performed by moving the substrate from the growth furnace of the MOVPE apparatus to a different place.

The atmosphere gas during cooling may contain oxygen. When a gas containing oxygen is used, JP-A-2003-297842, JP-A-10-209493 and the like may be referred to. A gas containing oxygen may be introduced into the growth furnace after the substrate temperature reaches not more than 700° C. The gas to be flown in the growth furnace during the above-mentioned growth interruption time may contain oxygen.

### [Electrode Formation Step]

The p-side electrode P12 of LED 10 in FIG. 1 is an Al/Pd/Au laminate electrode and its Al layer is in contact with p-side contact layer 16. The electrode shows a low contact resistance to the p-side contact layer 16, because, it is considered, Al is a metal forming a good ohmic contact with the n-type nitride semiconductor.

The p-side electrode P12 can be a single-layered Al film. The material is not limited to pure Al, and an Al alloy containing an element other than Al can be used so long as the contact resistance does not increase markedly.

Furthermore, Ti, W (tungsten), Cr (chrome) and the like can be used as other metal materials.

Not being a metal material, a transparent conducting film made of indium-tin oxide (ITO) can also be used as a p-side electrode P12.

When Al is used as a p-side electrode P12, since the difference in the thermal expansion coefficient between Al and a nitride semiconductor is comparatively great, when heat cycle occurs during the production step of an element or use of the element, a stress may be developed between the p-side electrode P12 and the p-side contact layer 16 and deformation of Al film may occur.

To suppress the problem, an Al alloy containing an element that enhances the heat resistance of Al is preferably used. As such element, Ti, Si, Nd, Cu and the like can be mentioned and, particularly, an alloy of Al and Ti is preferable since Ti shows a good ohmic contact with an n-type nitride semiconductor.

As a method for forming a p-side electrode P12 on the surface of the p-side contact layer 16, a conventionally known method may be appropriately referred to, and vapor phase methods such as vapor deposition, sputtering, CVD and the like are preferably recited as examples. After formation of the p-side electrode P12, a heat treatment of 300° C.-500° C. is preferably performed to reduce the contact resistance between an electrode film and the p-side contact layer 16.

In addition, as the method for forming an alloy film, conventionally-known methods can be referred to, and alloy sputtering, multi-source deposition, and a method comprising laminating a thin film made of each single component metal and heat treatment can be mentioned. For example, an Al—Ti alloy film can be obtained by a method comprising forming a laminate film of an Al film and a Ti film by vapor deposition, and heat treating at not less than 400° C.

Since Al shows good reflexivity in visible wavelength (green)—near ultraviolet wavelength, which is a typical emission wavelength of nitride LED, when at least a part of the p-side electrode P12 that comes into contact with the p-side contact layer 16 is formed with an Al layer (or Al alloy layer) formed to have a film thickness permitting light reflexivity, light absorption by electrode P12 becomes small and the emission efficiency of LED increases. Thus, the thickness of the Al layer or Al alloy layer is preferably set to not less than 10 nm, more preferably not less than 20 nm. While the surface of Al is easily oxidized, such film thickness prevents easy degradation and instability of the electrode property due to the surface oxidation.

In a p-side electrode P12 having a three-layer structure of Al/Pd/Au, the Au layer becomes a chemical protection layer of the whole electrode since it is superior in corrosion resistance. In addition, since an oxide film is not easily formed on the surface, it also has an effect of increasing the wettability with a brazing material (Au, Au—Sn entectic etc.) used for flip-chip bonding and the like.

A Pd layer is a barrier layer for suppressing alloying of Au of the Au layer by diffusing into an Al layer, thereby deteriorating the electric property or optical property of the Al layer. It also aims at preventing Al of the Al layer from diffusing into the Au layer, precipitating on a surface of the Au layer and forming an oxide film.

The barrier layer is not limited to the Pd film, and a metal having a melting point higher than that of Au can be used. The barrier layer can be a single layer film or multi-layer film comprising a single substance or alloy of Ti, W, Pd, Nb, Mo (molybdenum), Pt, Rh, Ir (iridium), Zr (zirconium), Hf (hafnium), Ni and the like. A preferable alloy is, for example, a W—Ti alloy. The barrier layer may be an alternately laminated film of a layer of these metals and an Au layer, and an alternately laminated film of a Pt layer and an Au layer is one of the preferable barrier layers.

For the p-side electrode P12 comprising 3 layers of Al layer/barrier layer/Au layer, a preferable thickness of the Al layer is 10 nm-70 nm, a preferable thickness of the barrier layer is 10 nm-300 nm, and a preferable thickness of the Au layer is 50 nm-2000 nm.

The p-side electrode P12 should be an electrode with an opening to extract the light generated in the active layer 14 to the outside of the element through the p-side electrode P12. When the p-side electrode P12 is a transparent conductive film made from ITO, an electrode with an opening is not necessary since the electrode material has light permeability.

It is also possible to employ a constitution where the light generated in the active layer 14 is taken out from the element from the sapphire substrate side 11. In this case, the p-side electrode P12 is preferably a reflective metal electrode rather than an electrode with an opening. In a reflective metal electrode, at least a part to be in contact with p-side contact layer 16 is preferably formed with a Al layer or Al alloy layer having good reflexivity.

The step for exposing the surface of the n-type contact layer 12 by dry etching, and forming an n-side electrode P11 on the exposed surface is not particularly limited, and a conventionally-known method can be referred to. This step can be performed after the completion of the above-mentioned substrate cooling step, which may be before or after the above-mentioned electrode formation step.

The above-mentioned exposed surface may be formed first, and then an n-side electrode P11 or a p-side electrode P12 may be formed. Here, either of the n-side electrode P11 or the p-side electrode P12 may be formed first. Alternatively, these electrodes may be simultaneously formed using the same material.

### PREFERABLE EMBODIMENT 1

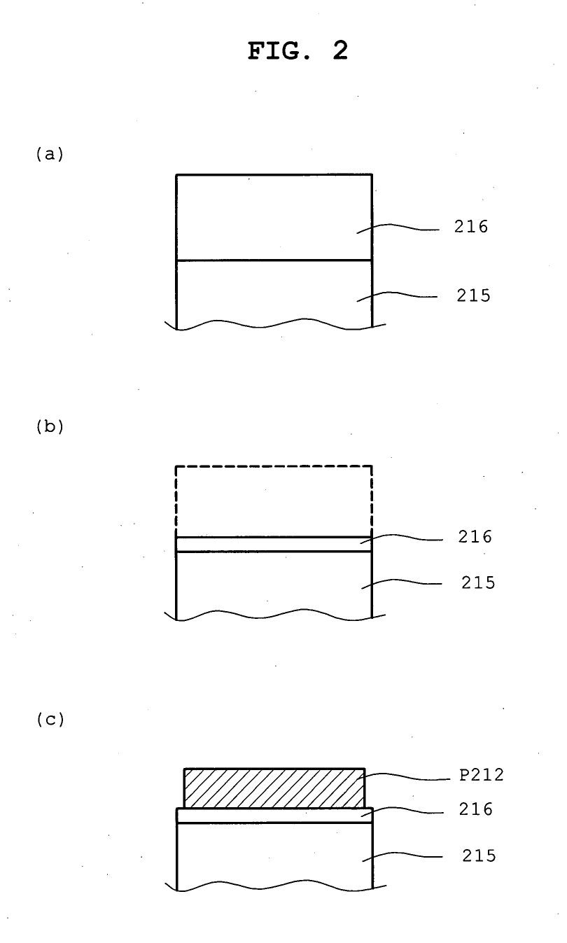

As a preferable example of the embodiment explained above, an embodiment wherein, in the above-mentioned semiconductor growing step, an n-type nitride semiconductor layer 216 is grown on a p-type clad layer 215 as shown in FIG. 2(a) and, after completion of the above-mentioned substrate cooling step, the surface side is removed by dry etching, leaving a part of the n-type nitride semiconductor layer 216 as shown in FIG. 2(b), and a p-side electrode P212 is formed on the surface of the remaining part of the layer 216 as a p-side contact layer as shown in FIG. 2(c) can be mentioned.

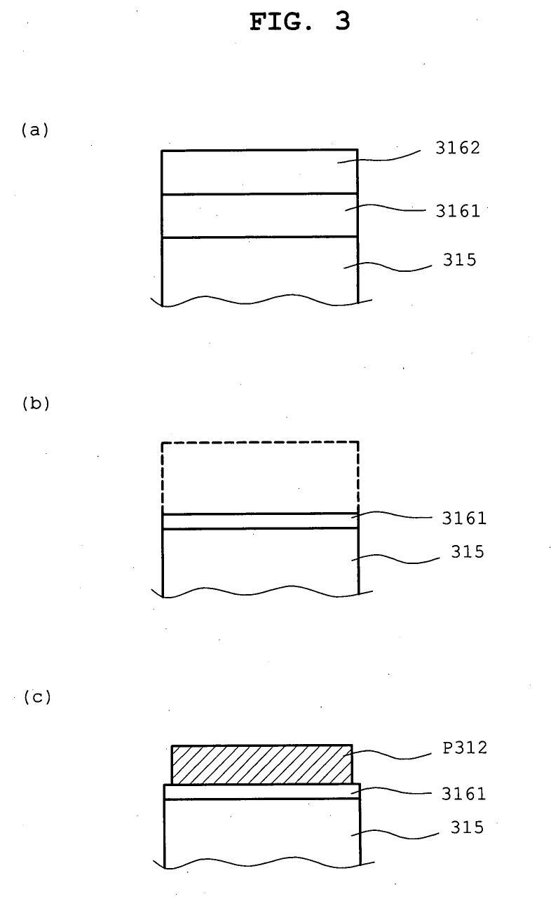

Moreover, in a semiconductor growing step, an n-type nitride semiconductor layer 3161 may be formed on the p-type clad layer 315, and any nitride semiconductor layer 3162 is grown thereon as shown in FIG. 3(a), after which a part on the surface side including the above-mentioned any nitride semiconductor layer 3162 is removed by dry etching, leaving a part of the n-type nitride semiconductor layer 3161, as shown in FIG. 3(b), a p-side electrode P312 is formed on the surface of the remaining part of the layer 3161 as a p-side contact layer as shown in FIG. 3(c).

In these embodiments, the surface damaged by exposure to the atmosphere in the substrate cooling step can be removed by dry etching, and a p-side electrode can be formed on the newly exposed surface of the n-type nitride semiconductor. Dry etching has an action to remove a native oxide film formed on the surface of a nitride semiconductor, and an action to remove contamination. Accordingly, by forming an electrode on the surface exposed by dry etching, contact resistance of an electrode can be decreased and the adhesion between an electrode and a semiconductor can be improved.

Formation of an electrode made of Al, Ti, ITO etc. on the surface exposed by dry etching is performed for n-side electrodes of conventional nitride LEDs, and good electric contact and adhesion are known to be obtained.

The production method of the present invention wherein a p-side electrode is formed on the surface of the n-type nitride semiconductor exposed by dry etching is also useful even when p-type impurity is activated by a conventional annealing. This is because, in this annealing treatment, although the surface of the nitride semiconductor layer formed as the uppermost layer is easily damaged since heating is applied in an atmosphere where the concentration of a V-group source material such as ammonia and the like is low, the damaged surface layer can be removed by dry etching. In addition, an action to remove a native oxide film, and an action to remove contamination are of course expected.

According to the prior art, formation of a p-side electrode on a dry-etched surface has been difficult. In conventional nitride semiconductor elements, a p-side electrode is formed on a p-type contact layer. However, when the p-type contact layer is dry-etched, nitrogen vacancy, which is an n-type defect, is formed to decrease the hole concentration. Therefore, a p-side electrode having a low contact resistance cannot be formed on the surface of the dry-etched p-type contact layer.

In contrast, in the production method of the present invention, such a problem does not occur because a p-side electrode of Al, Ti, ITO and the like is formed on a surface of an n-type nitride semiconductor layer.

For a dry etching method of a nitride semiconductor used in this embodiment, conventional known techniques can be referred to and, as a preferable method, plasma etching (reactive plasma etching, reactive ion etching) using a halogen compound or a halogen gas such as CF₄, CCl₂F₂, CCl₄, BCl₃, SiCl₄, Cl₂ and the like as a reaction gas is exemplified.

In an example shown in FIG. 2, dry etching is evenly performed on a surface of an n-type nitride semiconductor layer 216 grown on a p-type clad layer 215 to make entirely thin layer. This dry etching may be partially performed on the n-type nitride semiconductor layer.

For example, if the dry etching is performed to form a concaves and convexes pattern extending the entire surface of the p-side contact layer, the surface of the nitride semiconductor layer becomes concaves and convexes, which can improve the light extraction efficiency of an LED.

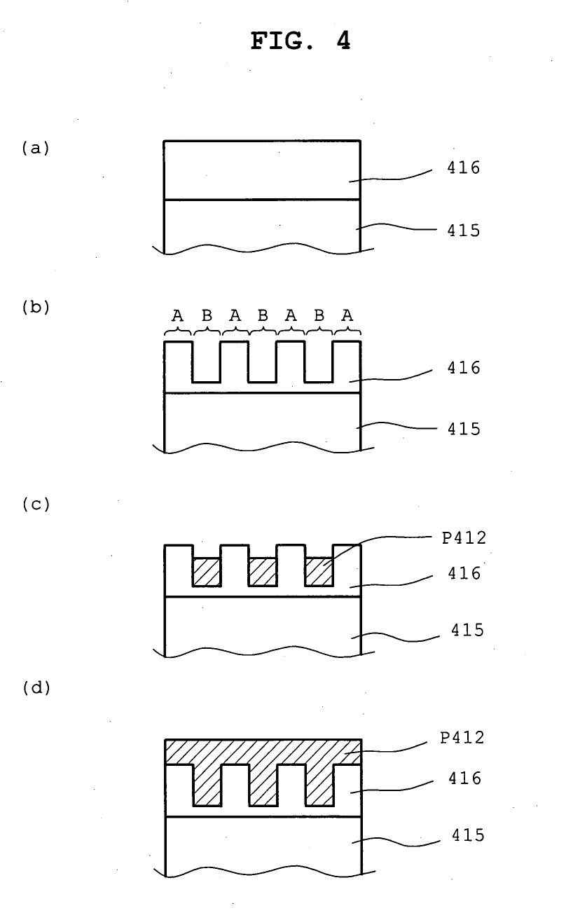

In this case, as shown in FIG. 4(a), an n-type nitride semiconductor layer 416 is first grown in a particular thickness on a p-type clad layer 415 in a semiconductor growing step. Here, the particular thickness is such thickness that is capable of setting the depth of a concave part formed by dry etching to not less than ¼ of the emission wavelength (wavelength in nitride semiconductor) of LED.

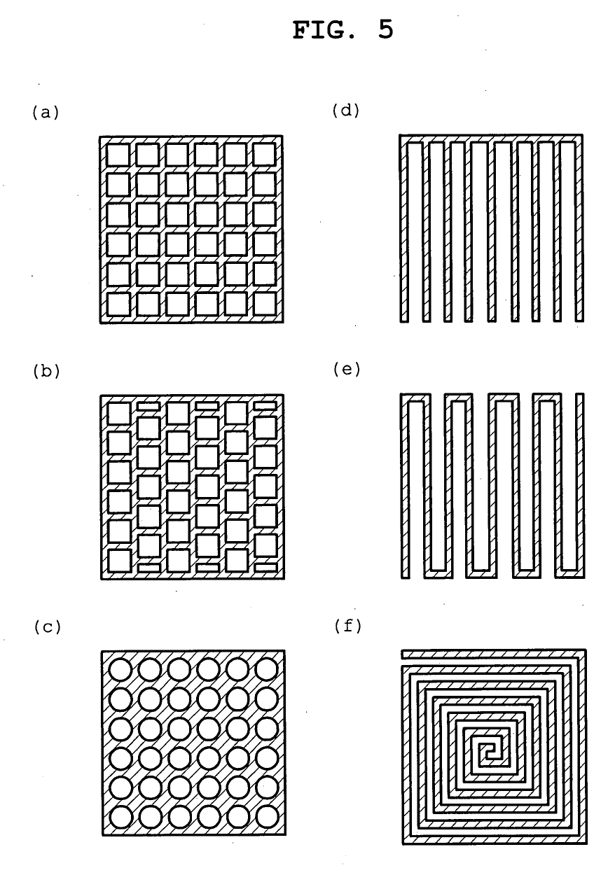

After the substrate cooling step, the surface of the above-mentioned n-type nitride semiconductor layer 416 is partially dry-etched to form a concave part B on the surface of the n-type nitride semiconductor layer 416, as shown in the sectional view of FIG. 4(b). Here, the pattern of the concave part B when seen from above the substrate includes nets as shown in FIG. 5(a)-(c), branch as shown in FIG. 5(d), meander as shown in FIG. 5(e), coil as shown in FIG. 5(f) and the like.

When making the depth of this concave part not less than one quarter of the emission wavelength (wavelength in the nitride semiconductor) of the LED, an effect of scattering the light emitting from the LED.

The cross section shape of the concaves and convexes may be a rectangle (including, besides square and oblong, trapezoid wherein an upper part of a convex is narrower than a base part, inverted trapezoid and the like) wave shape, triangular wave shape, sine curve shape, and the like.

When a reflective p-side electrode P412 is formed only on the concave part B of the n-type nitride semiconductor layer 416 as shown in FIG. 4(c) in the electrode formation step, a nitride LED capable of extracting the light generated in the active layer 14 from the p-side electrode P412 side can be afforded.

The nitride LED shows an improved light-extraction efficiency based on the light scattering effect due to concaves and convexes and easy extraction of the light to the outside from the convex part A protruding toward the light-extraction side.

As shown in FIG. 4(d), moreover, when a reflective p-side electrode P412 is formed to cover the whole concavo-convex surface, a nitride LED extracting light from the substrate side can be afforded. In this case, the light-extraction efficiency increases due to the light scattering effect.

In addition, when the electrode is formed with a transparent conductive film, a nitride LED extracting light from the transparent conductive film can be afforded. An electrode formed with a transparent conductive film, whether formed as shown in FIG. 4(c) or FIG. 4(d), gives a non-flat interface formed in the boundary between a p-side contact layer 416 and the transparent conductive film having different refractive indices. Therefore, the light-extraction efficiency of LED is improved by the light scattering effect.

To form a p-side electrode P412 as shown in FIG. 4(c), an etching mask having an opening having the pattern of concave part B is formed on the surface of the n-type nitride semiconductor layer 416 of FIG. 4(a), dry etching is performed to form the concave part B, and the electrode P412 is formed according to the vapor phase method while leaving the etching mask in the convex part A. Finally, the etching mask is removed to leave the electrode P412 only on the concave part B.

In this embodiment, when the depth of the concave part B is not less than 0.5 μm, the light scattering effect is particularly increased. Therefore, it is preferable to grow an n-type nitride semiconductor layer 416 to a thickness of not less than 0.5 μm in the semiconductor growing step, and make the depth of the dry etching not less than 0.5 μm.

Further, in this embodiment, an arbitrary nitride semiconductor layer can be further laminated on the n-type nitride semiconductor layer 416 grown on a p-type clad layer 415, and from the surface of this arbitrary nitride semiconductor layer, concave parts reaching the n-type nitride semiconductor layer 416 can be formed by partial dry etching.

When the p-side contact layer has sufficient thickness and sufficient conductivity, and the electric current can be sufficiently diffused within the p-side contact layer in the in-plane directions (direction perpendicular to thickness direction) of the layer, a p-side electrode can be formed at the site where formation of electrode does not cause difficulty in extracting the light generated in the active layer from the side of the p-side contact layer (e.g., edge, corner etc. of the chip).

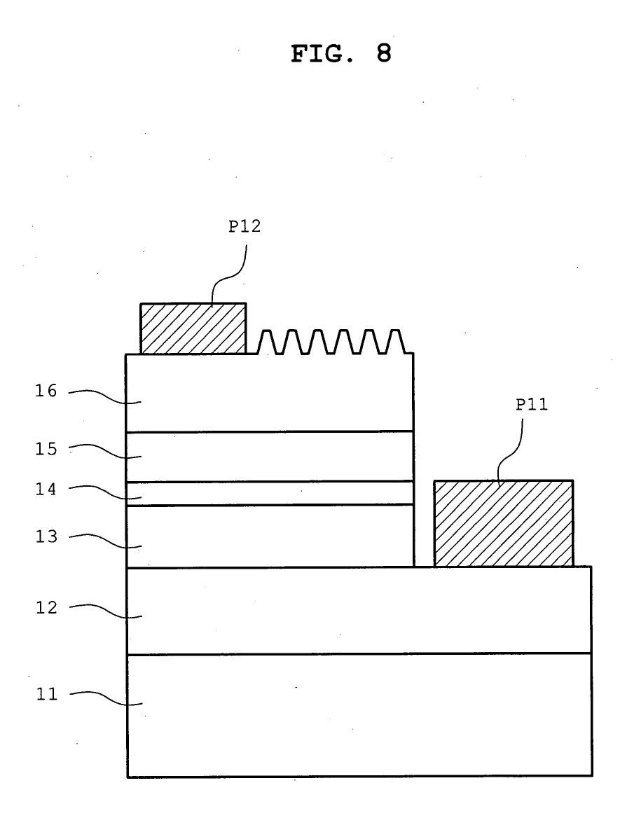

FIG. 8 shows one embodiment of the section structure of a light emitting element having a p-side electrode formed in this way, where a part of the p-side contact layer, that corresponds to the edge of a chip is partially dry-etched to remove the surface layer damaged in the substrate cooling step and a p-side electrode is formed on the exposed surface after removal of the surface layer. In the element shown in FIG. 8, not only the part where a p-side electrode is to be formed but also other surface areas of the p-side contact layer are dry-etched to give a concavo-convex surface.

While the element shown in FIG. 8 can be used in an embodiment where the light generated in the active layer is extracted from the substrate side, in this case, a reflective layer is preferably formed additionally in the area free of a p-side electrode on the surface of the p-side contact layer.

### PREFERABLE EMBODIMENT 2

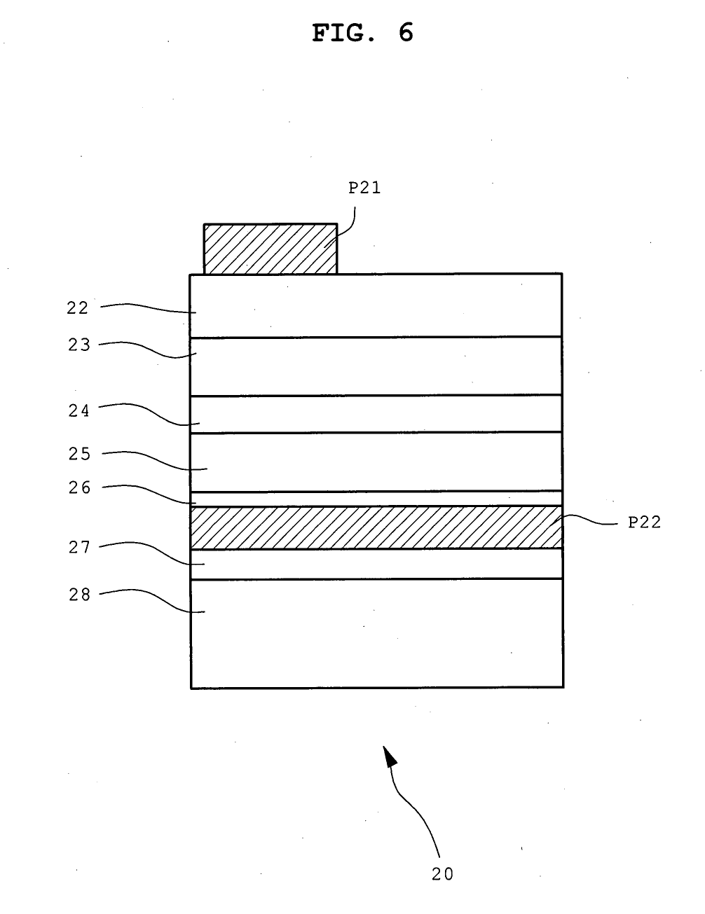

FIG. 6 is a schematic view of a section structure of other nitride LED of the present invention. LED 20 shown therein has a conductive supporting substrate 28, and a conductive bonding layer 27, a p-side electrode P22 having a three-layer structure (Al/Pd/Au) and in contact with a p-side contact layer 26 at an Al layer, a p-side contact layer (second n-type layer) 26 made of an n-type nitride semiconductor, a p-type clad layer 25 made of a p-type nitride semiconductor, an active layer 24 made of a nitride semiconductor, an n-type clad layer (the first n-type layer) 23 made of an n-type nitride semiconductor, and an n-type contact layer 22 made of an n-type nitride semiconductor are sequentially laminated on the supporting substrate 28. An n-side electrode P21 (Al/Pd/Au) is formed on the surface of the n-type contact layer 22 that forms an ohmic contact with the n-type nitride semiconductor at the Al layer.

LED 20 has an opposing electrode structure where an n-side electrode P21 and a p-side electrode P22 face each other via a laminate of a nitride semiconductor containing an active layer 24. While electricity feeding to the p-side electrode P22 is performed via the conductive supporting substrate 28 and the conductive bonding layer 27, the electrode to be formed on the supporting substrate 28 is not shown.

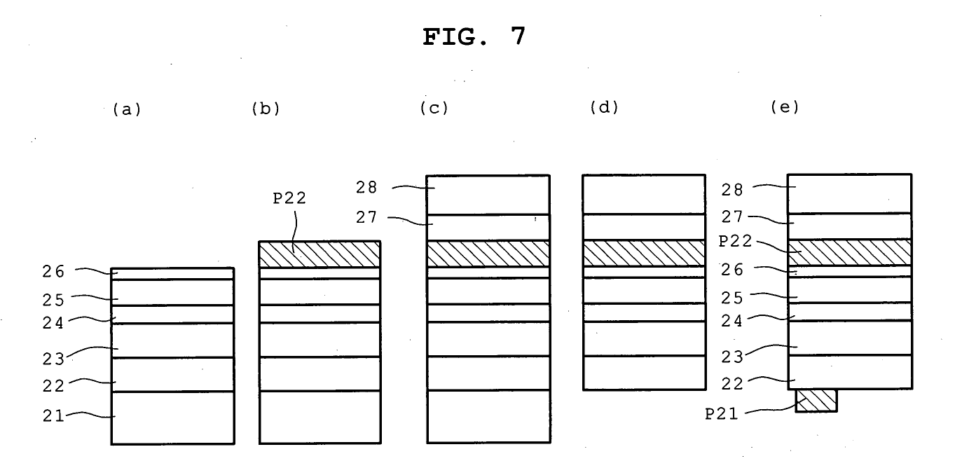

When this LED 20 is to be produced, as shown in FIG. 7(a), a semiconductor growing step is performed wherein a buffer layer not shown and nitride semiconductor layers from an n-type contact layer 22 to a p-side contact layer 26 are grown on a growth substrate 21 by the MOVPE method. Then, a substrate cooling step is performed wherein a p-type clad layer 25 is cooled to room temperature to become p-type conductive. Then, as shown in FIG. 7(b), an electrode formation step is performed wherein a p-side electrode P22 is formed on the surface of the p-side contact layer 26. Sequentially thereafter, a supporting substrate 28 is bonded to the surface of the p-side electrode P22 with a conductive bonding layer 27 (FIG. 7(c)), a growth substrate 21 is removed (FIG. 7(d)), and an n-side electrode P21 is formed on the surface of the n-type contact layer 22 exposed thereby (FIG. 7(e)).

The present invention includes a semiconductor growing step wherein a nitride semiconductor is grown on the substrate. However, it is not essential for the final objective nitride semiconductor element to contain the substrate to be used for the semiconductor growing step.

In the LED of FIG. 6, a supporting substrate 28 is bonded to the p-side electrode 22. However, it is also possible to bond, after removal of the growth substrate 21, the supporting substrate 28 to the n-type contact layer 22, as if the substrate 28 was exchanged with the growth substrate 21.

In addition, the present invention encompasses a production method, a nitride semiconductor element, and a light emitting diode, having the following characteristics.

(1a) A production method of a nitride semiconductor element, which comprises a semiconductor growing step comprising setting a substrate in a growth furnace of an MOVPE apparatus, and growing, on the substrate, a laminate of nitride semiconductor layers comprising a p-doped layer which is a nitride semiconductor layer doped with a p-type impurity and an n-doped layer to be laminated immediately thereabove, which is a nitride semiconductor layer doped with an n-type impurity, by the MOVPE method in such a manner that said n-doped layer becomes the uppermost layer of said laminate; after said semiconductor growing step, a substrate cooling step comprising cooling said substrate having a laminate grown thereon from said n-doped layer growth temperature to room temperature so that said p-doped layer will become p-type conductive; and after said substrate cooling step, an electrode formation step comprising forming, on the surface of said n-doped layer, an electrode for injecting a hole in said p-doped layer.
(2a) The production method of said (1a), wherein said n-doped layer has an electron concentration of 1×10¹⁸ cm⁻³-1×10²⁰ cm⁻³.
(3a) The production method of said (1a) or (2a), wherein said electrode comprises a metal capable of ohmic contact with an n-type nitride semiconductor.
(4a) The production method of said (1a) or (2a), wherein said electrode contains Al and/or Ti.
(5a) The production method of said (1a) or (2a), wherein said electrode is a transparent conductive film made of indium-tin oxide.
(6a) The production method of said (1a)-(5a), wherein a V-group source material to be used in said MOVPE method is ammonia and, in said semiconductor growing step, a growth interruption time is set between said growth of the p-doped layer and growth of said n-doped layer, during which time the ammonia concentration in the atmosphere in said growth furnace is lowered than that during the growth of said p-doped layer nitride, without growing the semiconductor.
(7a) The production method of said (6a), wherein a mixed gas containing ammonia and an inactive gas is supplied to said growth furnace, and the flow ratio of ammonia contained in the mixed gas is less than 2.5%, during said growth interruption time.
(8a) The production method of said (6a) or (7a), wherein the substrate temperature Tgn when growing said n-doped layer is lower than the substrate temperature Tgp when growing said p-doped layer, and the substrate temperature is decreased from Tgp to Tgn during said growth interruption time.
(9a) The production method of said (8a), wherein said Tgn is 700° C.-900° C.
(10a) The production method of any one of said (1a)-(9a), wherein a mixed gas containing ammonia and an inactive gas is supplied in said substrate cooling step.
(11a) The production method of said (10a), wherein the flow ratio of ammonia contained in said mixed gas is less than 2.5%.
(12a) The production method of said (10a) or (11a), wherein the supply of said mixed gas is stopped before the substrate temperature decreased to 400° C. or below.
(13a) The production method of any one of said (1a)-(12a), wherein said nitride semiconductor element is a light emitting element.
(14a) The production method of said (13a), wherein said light emitting element is a light emitting diode.
(15a) The production method of said (4a), wherein said nitride semiconductor element is a light emitting diode, and at least a part of said electrode to be in contact with the surface of said n-doped layer comprises a light reflective Al layer or Al alloy layer.
(16a) A production method of a nitride semiconductor element, which comprises (A) a growing step comprising setting a substrate in a growth furnace of an MOVPE apparatus, and growing, on the substrate, a laminate of nitride semiconductor layers comprising a first nitride semiconductor doped with a p-type impurity and a second nitride semiconductor layer to be laminated immediately thereabove, which is a nitride semiconductor layer doped with an n-type impurity, by the MOVPE method;
(B) after said step (A), a step comprising cooling said substrate having a laminate grown thereon from the growth temperature of the uppermost layer of said laminate to room temperature so that the first nitride semiconductor will become p-type conductive; (C) after said step (B), a step for dry etching from the surface side of said laminate to the depth leaving a part of said second nitride semiconductor layer on the surface of said first nitride semiconductor layer, and (D) after said step (C), a step comprising forming, on the surface exposed by said dry etching of said second nitride semiconductor layer, an electrode for injecting a hole in said p-doped layer.
(17a) The production method of said (16a), wherein the uppermost layer of said laminate is said second nitride semiconductor layer.
(18a) The production method of said (16a) or (17a), wherein said second nitride semiconductor layer has an electron concentration of 1×10¹⁸ cm⁻³-1×10²⁰ cm⁻³.
(19a) The production method of any one of said (16a)-(18a), wherein said electrode comprises a metal capable of ohmic contact with an n-type nitride semiconductor.
(20a) The production method of any one of said (16a)-(18a), wherein said electrode contains Al and/or Ti.
(21a) The production method of any one of said (16a)-(18a), wherein said electrode is a transparent conductive film made of indium-tin oxide.
(22a) The production method of any one of said (16a)-(21a), wherein, in said step (C), said dry etching is partially applied to said laminate.
(23a) A nitride semiconductor element comprising a substrate, a p-type nitride semiconductor layer formed on said substrate, an n-type nitride semiconductor layer formed immediately above said p-type nitride semiconductor layer and having a surface exposed by dry etching and an electrode for injecting a hole into said p-type nitride semiconductor layer, which is formed to be in contact with said surface exposed by dry etching.
(24a) A light emitting diode comprising a substrate, a p-type nitride semiconductor layer formed on said substrate, a nitride semiconductor layer formed immediately above said p-type nitride semiconductor layer, which comprises an n-type nitride semiconductor at least in the part to be in contact with said p-type nitride semiconductor layer, and a concave part processed by dry etching from the surface on the opposite side from the side in contact with said p-type nitride semiconductor layer to reach said n-type nitride semiconductor, and an electrode for injecting a hole into said p-type nitride semiconductor layer, which is formed on the surface of the n-type nitride semiconductor exposed in said concave part.

In nitride LEDs having conventional structures, the inside of a p-type clad layer and a p-type contact layer can be made p-type conductive by lowering the ammonia concentration in the atmosphere during cooling after growth of the semiconductor layer. However, when the ammonia concentration is too low, surface degradation is developed in the vicinity of the surface of a p-type contact layer, hole concentration decreases due to the action of the nitrogen vacancy generated therealong, and a p-side electrode shows an increased contact resistance. When a small amount of ammonia is added to the cooling atmosphere to suppress the increased contact resistance, hydrogen passivation is developed to reduce the hole concentration, which again causes an increased contact resistance of the p-side electrode. In other words, nitride LEDs having conventional structures and using a p-type contact layer have a limitation on the suppression of contact resistance of a p-side electrode.

In contrast, according to the production method of the nitride semiconductor element of the present invention, after growth of a nitride semiconductor layer doped with a p-type impurity, a nitride semiconductor layer doped with an n-type impurity is further grown immediately thereabove, the laminate is cooled, and a p-side electrode is formed on the surface of the nitride semiconductor doped with the n-type impurity. As a result, the problem of the prior art that the contact resistance of a p-side electrode increases when the ammonia concentration of the cooling atmosphere is too high or too low can be solved. This is because a nitride semiconductor doped with an n-type impurity is considered to be free of a decreased carrier (electron) concentration due to hydrogen passivation, as well as a decreased carrier (electron) concentration due to surface degradation.

Accordingly, according to the production method of the nitride semiconductor element of the present invention, using a one-stage formation method for forming a p-type nitride semiconductor layer, a nitride semiconductor element having a low contact resistance of a p-side electrode can be produced, which in turn affords a nitride semiconductor element having a low operating voltage.

### EXAMPLES

### Example 1

A C-plane sapphire substrate of 2 inches diameter was mounted on a susceptor placed in a growth furnace in MOVPE apparatus and the surface was thermal cleaned while increasing the substrate temperature to 1100° C. under hydrogen atmosphere. After that, the substrate temperature was lowered to 330° C., and an AlGaN low temperature buffer layer of 20 nm in thickness was grown using TMG and TMA as a III-group source material and ammonia as a V-group source material. Subsequent to the growth of this AlGaN low temperature buffer layer, at the time of growth of a nitride semiconductor layer, a nitrogen gas was supplied into the growth furnace as a sub-flow gas, and a hydrogen gas was used as a carrier gas for a III-group source material and a V-group source material.

Subsequently, the substrate temperature was raised to 1000° C., TMG and ammonia were supplied as source materials to grow an undoped-GaN layer by 2 μm, and then silane was further supplied to grow an n-type clad layer (also used as an n-type contact layer) of 3 μm in thickness made of Si-doped GaN.

Subsequently, the substrate temperature was lowered to 800° C., and an active layer of a multiquantum well structure comprising alternately laminated 10 layers of each GaN barrier layer and InGaN well layer (the emission wavelength 405 nm) was formed. Trimethylindium was used as an In source material for growing the well layer.

Next, the substrate temperature was raised to 1000° C., bis(ethylcyclopentadienyl)magnesium (EtCp₂Mg) of Mg source material, TMG, TMA, and ammonia were supplied, and a first p-type clad layer comprising Mg-doped AlGaN was grown by 50 nm. Subsequently, the supply of TMA was stopped and a second p-type clad layer comprising Mg-doped GaN was grown by 50 nm. The Mg concentration of this second p-type clad layer was set to 2×10²⁰ cm⁻³.

Next, the supply of EtCp₂Mg, TMG, TMA and hydrogen gas (carrier gas) was stopped, the substrate temperature was lowered to 800° C. while supplying ammonia and nitrogen gas into the growth furnace so that the flow rate of ammonia would be 0.5%. The temperature lowering was stopped when the substrate temperature became 800° C., the former flow of ammonia was once again restored, and TMG and silane were supplied to grow a p-side contact layer of 100 nm in thickness made of n-type GaN of 1×10¹⁹ cm⁻³ in Si concentration.

After growth of the p-side contact layer, heating of the substrate and the supply of the source materials were stopped, and natural cooling was performed to the room temperature while flowing only nitrogen into the growth furnace.

Thus, a wafer having a near ultraviolet LED structure with the emission wavelength of 405 nm was obtained.

Next, by RIE (reactive ion etching) using Cl₂ gas, a surface layer part of the p-side contact layer was removed from the entire wafer surface and the film thickness of the p-side contact layer was set to 50 nm.

Next, RIE was further performed on a topical region of an upper surface of p-side contact layer, delving down from the upper surface to the lower layer side, successively removing the p-side contact layer, second p-type clad layer, first p-type clad layer and active layer, to topically expose an n-type clad layer.

Next, on each surface of the p-side contact layer and the n-type clad layer exposed by the aforementioned RIE, an electrode of a three-layer structure laminated with an Al layer of 20 nm in thickness, a Pd layer of 50 nm in thickness and an Au layer of 100 nm in thickness in this order was simultaneously formed by an electron beam vapor deposition method.

Here, a p-side electrode formed on a surface of the p-side contact layer was shaped in a lattice mesh pattern using photolithography technique. This lattice mesh pattern was a pattern having quadrate openings (the parts where the surface of p-side contact layer was exposed) of 6 μm on one side were disposed in square matrix with an interval of 2 μm both in length and width, namely, an orthogonal net-like pattern with an electrode part of 2 μm in width and an opening of 6 μm in width are repeated alternately in two directions perpendicular to each other.

Subsequently, on a p-side electrode and an n-side electrode, a pad electrode for wire bonding comprising a Ti layer of 30 nm in thickness and an Au layer of 300 nm in thickness laminated in this order was formed by an electron beam vapor deposition method. After that, using RTA (rapid thermal anneal) apparatus, this wafer was heat-treated for 500° C.×5 min. Lastly, a backside of the sapphire substrate was ground to the thickness of 90 μm and element separation was performed by general scribing and braking to give LED chip of 350 mm on one side.

After die bonding the LED chip prepared by the above-mentioned procedure on a stem table, current feeding was made possible by wire bonding and element properties were evaluated to find an output of 5.6 mW (at 20 mA) and forward voltage of 3.2 V (at 20 mA).

### Example 2

In the present Example, LED chip was prepared in the same manner as in Example 1, except that growth thickness was changed to 50 nm when growing the p-side contact layer by a MOVPE method, and a p-side electrode was formed on the surface of p-side contact layer as grown without removing a surface layer part of p-side contact layer by RIE, and was evaluated.

As a result, while the output was equivalent to that of Example 1, the forward voltage was 3.6 V (at 20 mA).

### Reference Experimental Example 1

The results of an experiment conducted in order to evaluate the performance of a light emitting element of the present invention are shown as follows.

A C-plane sapphire substrate of 2 inches diameter was mounted on a susceptor placed in a growth furnace in MOVPE apparatus and the surface was thermal cleaned while increasing the substrate temperature to 1100° C. under hydrogen atmosphere. After that, the substrate temperature was lowered to 330° C., and an AlGaN low temperature buffer layer of 20 nm in thickness was grown using TMG and TMA as a III-group source material and ammonia as a V-group source material. Subsequent to the growth of this AlGaN low temperature buffer layer, at the time of growth of a nitride semiconductor layer, a nitrogen gas was supplied into the growth furnace as a sub-flow gas, and a hydrogen gas was used as a carrier gas for a III-group source material and a V-group source material.

Subsequently, the substrate temperature was raised to 1000° C., TMG and ammonia were supplied as source materials to grow an undoped-GaN layer by 2 μm, and then silane was further supplied to grow an n-type clad layer (also used as an n-type contact layer) of 3 μm in thickness made of Si-doped GaN.

Subsequently, the substrate temperature was lowered to 800° C., and an active layer of a multiquantum well structure comprising alternately laminated 10 layers of each GaN barrier layer and InGaN well layer (the emission wavelength 405 nm) was formed. Trimethylindium was used as an In source material for growing the well layer.

Next, the substrate temperature was raised to 1000° C., bis(ethylcyclopentadienyl)magnesium (EtCp₂Mg) of Mg source material, TMG, TMA, and ammonia were supplied, and a first p-type clad layer comprising Mg-doped AlGaN was grown by 50 nm. Subsequently, the supply of TMA was stopped and a second p-type clad layer comprising Mg-doped GaN was grown by 200 nm.

Next, the supply of EtCp₂Mg, TMG, TMA and hydrogen gas (carrier gas) was stopped, the substrate temperature was lowered to 800° C. while supplying ammonia and nitrogen gas into the growth furnace so that the flow rate of ammonia would be 0.5%. The temperature lowering was stopped when the substrate temperature became 800° C., the former flow of ammonia was once again restored, and TMG and silane were supplied to grow a p-side contact layer of 10 nm in thickness made of n-type GaN of 1×10¹⁹ cm⁻³ in Si concentration.

After the growth of p-side contact layer, heating of the substrate and the supply of the source materials were stopped, and natural cooling was performed to the room temperature while flowing only nitrogen into the growth furnace.

Thus, a wafer having a near ultraviolet LED structure with the emission wavelength of 405 nm was obtained.

Next, RIE using a Cl₂ gas was performed on a topical region of an upper surface of a nitride semiconductor layer grown on the wafer, delving down from the upper surface to the lower layer side, successively removing the p-side contact layer, second p-type clad layer, first p-type clad layer and active layer to topically expose an n-type clad layer.

Next, on a surface of the p-side contact layer and a surface of the n-type clad layer exposed by RIE, an electrode of a three-layer structure laminated with an Al layer of 20 nm in thickness, a Pd layer of 50 nm in thickness and an Au layer of 100 nm in thickness in this order was simultaneously formed by an electron beam vapor deposition method.

Here, a p-side electrode formed on a surface of the p-side contact layer was shaped in a lattice mesh pattern using photolithography technique. This lattice mesh pattern was a pattern having quadrate openings (the parts where the surface of p-side contact layer was exposed) of 6 μm on one side were disposed in square matrix with an interval of 2 μm both in length and width, namely, an orthogonal net-like pattern with an electrode part of 2 μm in width and an opening of 6 μm in width are repeated alternately in two directions perpendicular to each other.

Subsequently, on a p-side electrode and an n-side electrode, a pad electrode for wire bonding comprising a Ti layer of 30 nm in thickness and an Au layer of 300 nm in thickness laminated in this order was formed by an electron beam vapor deposition method. After that, using RTA (rapid thermal anneal) apparatus, this wafer was heat-treated for 500° C.×5 min. Lastly, a backside of the sapphire substrate was ground to the thickness of 90 μm and element separation was performed by general scribing and braking to give LED chip of 350 mm on one side.

After die bonding the LED chip prepared by the above-mentioned procedure on a stem table, current feeding was made possible by wire bonding and element properties were evaluated to find an output of 5.4 mW (at 20 mA) and forward voltage of 3.6 V (at 20 mA).

### Reference Experimental Example 2

LED chip was prepare in the same manner as in Reference Experimental Example 1, except that, after growing the second p-type clad layer, a p-side contact layer was grown at the same substrate temperature without changing it, and then, concurrently with stopping of heating of the substrate, supply of the III-group source material was stopped, and the substrate was naturally cooled to the room temperature while flowing ammonia and nitrogen gas into the growth furnace so that the flow rate of ammonia would be 2% and the element properties were evaluated to find output of 5.3 mW (at 20 mA), forward voltage of 3.9 V (at 20 mA).

### Reference Experimental Example 3

LED chip was prepared in the same manner as in the above-mentioned Reference Experimental Example 2, except that, after completion of the growth of p-side contact layer, natural cooling was performed to the room temperature while flowing only nitrogen into the growth furnace, and the element properties were evaluated to find output 5.2 mW (at 20 mA), forward voltage 4.0 V (at 20 mA).

### Reference Experimental Example 4

LED chip was prepared in the same manner as in Reference Experimental Example 1 except that a p-side electrode and an n-side electrode were made as a two-layer structure comprising a Ti layer of 20 nm in thickness and an Al layer of 200 nm in thickness, laminated in this order, and the element properties were evaluated to find an output 5.0 mW (at 20 mA), forward voltage 3.6 V (at 20 mA).

### Reference Experimental Example 5

LED chip was prepared in the same manner as in Reference Experimental Example 1 except that, instead of a p-side contact layer of n-type GaN of 10 nm in thickness, a p-type contact layer of 10 nm in thickness made of p-type GaN having Mg concentration of 5×10²⁰ cm⁻³ was formed and the p-side electrode was made as a two-layer structure comprising an Ni layer of 20 nm in thickness and an Au layer of 150 nm in thickness laminated in this order, and the element properties were evaluated.

As a result of the evaluation, it was found that the output was 5.0 mW (at 20 mA) and the forward voltage was 4.5 V (at 20 mA).

### Reference Experimental Example 6

LED chip was prepared in the same manner as in Reference Experimental Example 2 except that, instead of the p-side contact layer of n-type GaN of 10 nm in thickness, a p-type contact layer of 10 nm in thickness made of p-type GaN having Mg concentration of 5×10²⁰ cm⁻³ was formed and the p-side electrode was made as a two-layer structure comprising an Ni layer of 20 nm in thickness and an Au layer of 150 nm in thickness laminated in this order, and the element properties were evaluated.

As a result of the evaluation, it was found that the output was 5.0 mW (at 20 mA) and the forward voltage was 5.5 V (at 20 mA).

### Reference Experimental Example 7

LED chip was prepared in the same manner as in Reference Experimental Example 3 except that, instead of a p-side contact layer of n-type GaN of 10 nm in thickness, a p-type contact layer of 10 nm in thickness made of p-type GaN having Mg concentration of 5×10²⁰ cm⁻³ was formed and the p-side electrode was made as a two-layer structure comprising an Ni layer of 20 nm in thickness and an Au layer of 150 nm in thickness laminated in this order, and the element properties were evaluated.

As a result of the evaluation, it was found that the output was 4.0 mW (at 20 mA) and the forward voltage was 3.5 V (at 20 mA).

While the forward voltage was a comparatively low value in Reference Experimental Example 7, since a drastic decrease in the reverse breakdown voltage (Vr) and an increase in the leak current were simultaneously observed, it is considered that the resistance of the element decreased since current flow was facilitated through a leak current pass, and the results apparently show that the operating voltage decreased.

### INDUSTRIAL FIELD OF UTILIZATION

The structure of LED according to an embodiment of the present invention is not limited to the structures of FIG. 1 and FIG. 6 but can be variously modified in reference to known techniques.

The present invention is useful as a production method of not only LED but also any nitride semiconductor element (light emitting element other than LED, light receiving element, electron device etc.) having a p-type nitride semiconductor layer and an electrode for injecting a hole in the layer. In this case, structure of the element and techniques necessary for its production may be appropriately found in known techniques.

This application is based on application No. 2004-289466 filed in Japan, the contents of which are incorporated hereinto by reference.

1. A nitride semiconductor light emitting element comprising a laminate made of nitride semiconductor layers, the laminate including:
one light emitting part having a laminate structure of a first n-type layer, a p-type layer and an active layer sandwiched between them, and
a second n-type layer present at the outer side of the light emitting part and at the p-type layer side, wherein
the second n-type layer has a surface exposed by dry etching, and a p-side electrode for injecting a hole into the p-type layer of said light emitting part is formed on the exposed surface, the p-side electrode being formed by using a material selected from the group consisting of Al, Ti, W, Cr and ITO, and
wherein the laminate is formed by sequentially growing nitride semiconductor layers on the substrate,
when the substrate is on the lower side, the light emitting part is included in the laminate in such a manner that the first n-type layer is on the lower side and the p-type layer is on the upper side, and
the second n-type layer is located at the upper side of the light emitting part.

2-5. (canceled)

6. The nitride semiconductor light emitting element of claim 1, wherein the entire upper surface of the second n-type layer is dry etched, and the p-side electrode is formed on the dry etched surface.

7. The nitride semiconductor light emitting element of claim 6, wherein the p-side electrode is formed on approximately the entire surface of the above-mentioned dry etched surface.

8. (canceled)

9. The nitride semiconductor light emitting element of claim 1, wherein the dry etched side of the surface of the second n-type layer is a concavo-convex surface formed by the dry etching.

10. The nitride semiconductor light emitting element of claim 9, wherein the surface of the dry etched side of the second n-type layer has a nitride semiconductor layer layered on said surface prior to the dry etching, the dry etching is applied to the second n-type layer from the surface of the layered nitride semiconductor layer to reach the second n-type layer.

11. The nitride semiconductor light emitting element of claim 9, wherein the p-side electrode is formed on approximately the entire surface of the concavo-convex surface.

12. (canceled)

13. The nitride semiconductor light emitting element of claim 9, wherein the p-side electrode is formed only in the concave part of the concavo-convex surface, and the p-side electrode is absent in the upper part of the convex part.

14. A method for producing a nitride semiconductor light emitting element comprising an element structure wherein a laminate including one light emitting part having nitride semiconductor layers is grown on a substrate, which comprises at least
a step of growing a first n-type layer, an active layer, a p-type layer and a second n-type layer in this order on the substrate,
a step of applying dry etching to the upper surface of said second n-type layer, and
a step of forming a p-side electrode on the surface of the second n-type layer which has been exposed by dry etching in said step, the electrode being used for injecting a hole into the p-type layer of the light emitting part, the p-side electrode being formed by using a material selected from the group consisting of Al, Ti, W, Cr and ITO, and
wherein the laminate is formed by sequentially growing nitride semiconductor layers on the substrate,
when the substrate is on the lower side, the light emitting part is included in the laminate in such a manner that the first n-type layer is on the lower side and the p-type layer is on the upper side, and
the second n-type layer is located at the upper side of the light emitting part.

15. (canceled)

16. The nitride semiconductor light emitting element of claim 10, herein the p-side electrode is formed on approximately the entire surface of the concavo-convex surface.

17. (canceled)

18. The nitride semiconductor light emitting element of claim 10, wherein the p-side electrode is formed only in the concave part of the concavo-convex surface, and the p-side electrode is absent in the upper part of the convex part.

19. The nitride semiconductor light emitting element of claim 1, wherein the material of the p-side electrode is an Al alloy containing an element enhancing the heat resistance of Al.

20. The nitride semiconductor light emitting element of claim 19, wherein the element enhancing the heat resistance of Al is selected from the group consisting of Ti, Si, Nd and Cu.

21. The nitride semiconductor light emitting element of claim 19, wherein the material of the p-side electrode is an Al alloy containing Ti.
